(19) United States
(12) Patent Application Publication
(10) Pub. No.: US 2015/0287850 A1
(43) Pub. Date: Oct. 8, 2015

(54) Solar Cell and Method for Manufacturing

(71) Applicant: Giga Solar Materials Corporation, Hsinchu County (TW)

(72) Inventors: Kuo-Hsun Tai, Hsinchu City (TW); Mi-Han Li, Hsinchu County (TW); Chung-Chieh Cheng, Hsinchu City (TW); Shing-Jiun Chen, Taichung City (TW)

(21) Appl. No.: 14/743,194

(22) Filed: Jun. 18, 2015

Related U.S. Application Data
(63) Continuation of application No. 13/560,381, filed on Jul. 27, 2012.

(51) Int. Cl. H01L 31/0224

(52) U.S. Cl. CPC H01L 31/022425

(57) ABSTRACT

The present invention provides a solar cell with a conductive composition which comprises a conductive functional phase mixture. The conductive functional phase mixture is made of a metal and a metal oxide, wherein the metal oxide is as the filler and the metal is as the main body. A coating portion covers substantially at least a partial surface of the filler, wherein the coating portion includes at least silver or copper.

### CROSS-REFERENCE TO RELATED APPLICATION

This application is a continued application (CA) of U.S. patent application Ser. No. 13/560,381, titled “Conductive Composition and Method for Manufacturing” filed on Jul. 27, 2012.

### TECHNICAL FIELD

The present invention generally relates to a solar cell, more particularly, to a solar cell with a conductive composition applied to the solar cell and the fabricating method thereof.

### BACKGROUND

Solar cells are capable of converting radiation of light into electricity via the semiconductor material thereof. The structure of the solar cell includes a photoelectric conversion layer, and the photoelectric conversion layer is made by the PN junction formed by a P-type semiconductor material and a N-type semiconductor material. When the sunlight irradiates on the photoelectric conversion layer, a band of light corresponding to the semiconductor material is absorbed by the photoelectric conversion layer such that the light energy is converted into electricity in the form of the electron-hole pairs in order to achieve the photoelectric conversion, and supplied for the metal wire connected to the P-type semiconductor material layer and the N-type semiconductor material layer.

The solar cell is a semiconductor device capable of converting light energy to electricity by the photovoltaic effect. Basically, any semiconductor diode can be used to convert light energy into electrical energy. The solar cells generate electricity based on two factors of the photoconductive effect and the internal electric field. Therefore, the choice of materials of the solar cells needs to be considered its photoconductive effect and how to generate its internal electric field.

The performance of a solar cell is mainly determined by the conversion efficiency between light and electricity. The factors that would have an impact on the conversion efficiency include: the intensity and temperature of sunlight; resistance of the material and the quality and defect density of the substrate; concentration and depth of the p-n junction; surface reflectance against light; the line width, line height and contact resistance of the metal electrode. Hence, in order to produce solar cells with high conversion efficiency, tight control towards each of the impact factors mentioned above is necessary.

The conversion efficiency and cost of production are the main considerations for producing solar cells today. Among the solar cell products on the market today, solar cells made by silicon have the greatest market share. Categorizing by crystal structure, they can be divided into single-crystal silicon solar cell, polycrystalline silicon solar cell and amorphous silicon solar cell. From the perspective of conversion efficiency, single-crystal silicon solar cell is the most efficient with approximately 24% conversion efficiency, whereas polycrystalline silicon is about 19% and amorphous silicon is roughly 11%. By using other compound semiconductors as the light-electric conversion substrate, such as the III-V compound semiconductor GaAs, the conversion efficiency can be raised to 26% and above.

Approaching innovation mechanism to raise the energy conversion efficiency and lowering the thickness of silicon wafers is another major focus in the development of solar cell technology. With the problem of wafer thickness, existing technology utilizes a laser-fired contact (LFC) process to lower the thickness of the cell to below 37 μm, and raise the efficiency level to 20%. The steps involved are roughly illustrated as follows: the evaporation process is introduced to create an aluminum layer and a passivation layer is thereby forming on the back of the solar cell, and the laser beams is utilized to penetrate the aluminum layer and form conducting contacts. The previous problem of losing electric energy may be resolved by the LFC technology and in addition, the traditionally expensive lithography and etching technology used to form holes within the passivation layer (located on the back of the silicon substrate) for holding aluminum electrode, is no longer required.

Moreover, a current may be conducted by the two metal electrode terminals of the semiconductor substrate to the external load side such that the current generated by the solar cell is conducted out as an available electrical energy. Of course, the metal electrode will block the light-receiving side (ie, positive side) of the substrate to impede the absorption of sunlight, so an area of the metal electrode on the positive side of solar cells is as small as possible to increase the photo-receiving area of the solar cells. Therefore, the metal electrodes are generally made on positive/back side of the solar cells as mesh electrode structure by using screen printing technology. In electrode manufacturing, a conductive metal paste (such as silver paste) is printed on doped silicon substrate in accordance with the designed graph by using screen printing technology. Organic solvents in the conductive metal paste is volatilized in an available sintering condition such that metal particles interact with the surface of silicon to form silicon alloy as a good ohmic contact, and thus become a positive and back metal electrode of the solar cells. However, too thin electrode finger line could easily lead to the disconnection, or resistance increased, reducing the conversion efficiency of the solar cells. Therefore, it is the technical focus how to achieve the thinning without reducing the overall power efficiency of the cells. In general, the thickness of the metal electrode is about 10 to 25 microns (um), and the width of the positive metal line (finger line) is approximately 120˜200 microns. It has advantages of automation, high throughput and low cost by using such technology to produce the electrodes of the solar cells. In previous works, compositions of the conductive paste are likely to form a large cluster, which is not easily passing through the mesh of the screen printing or damaging screen printing plate.

In addition, for a silicon substrate (ie, non-light-receiving side) of the solar cells, the back electrode structure includes a silver electrode portion (finger line electrode portion) and an aluminum electrode portion (backside electric field portion). In general industry practice, the silver electrode 11 pattern is printed on the back of the silicon substrate 10 by using screen printing method, followed by the aluminum electrode 12 pattern formed on the silver electrode 11, as shown in FIG. 1. Due to the poor solder-ability of aluminum, solar cell modules can not be electrically connected for each others by soldering directly, so the solder ribbons 20 are generally soldered on the silver electrode 11 region of back of the solar cell such that the solar cell modules are electrically integrated form each others. In the structure of FIG. 1, the interface 30 between silver electrode-silicon substrate and the interface 50 between aluminum electrode-Si substrate will form a eutectic layer in the sintering process, and thereby bonding tightly. However, between silver and aluminum is difficult to form the eutectic structure, and the interface 40 between the silver electrode—the aluminum electrode is prone to peeling, making between the silver electrode and the aluminum electrode to produce cracks, and thereby lowering the solar cells overall performance. Therefore, in addition to the conversion efficiency of testing, after the solar cell module is fabricated, adhesion test of the solder ribbons 20 and peeling test between the interface 40 of silver electrodes-aluminum electrode may be performed to ensure the soundness of the back structure of the module.

As above-mentioned, in addition to the formation of the P-N junction semiconductor substrate, the main part of manufacturing the solar cells is the conductive composition. The known technology of the conductive composition is made by the metal powder (especially silver), glass frit, organic vehicle, and additives, and the composition, content, the proportion of process parameters will affect the performance of the final electrode product. Take the back of the metal electrode for example, in addition to adhesion strength of the solder ribbon and peeling extent of the interface between silver electrode-aluminum electrode, the quality of the conductive silver composition and aluminum composition will be directly impact to the conversion efficiency η, open circuit voltage Voc, short circuit current (Isc), fill factor, series resistance Rs, and the shunt resistance Rsh (shunt resistance) of the solar cell, and will determine the effective range of the sintering temperature Ts and the adhesion strength. Therefore, how to deploy a conductive composition to improve the above-mentioned solar cell performance is dominate for the industry developments.

Silver aluminum paste is generally contains silver powder and aluminum powder mixture. However, it is difficult to form a eutectic structure between silver and aluminum, resulting in poor adhesion between silver-aluminum conductive paste, and easily peeling between the silver and glass frit. If all of the conductive particles are used by the silver material, the cost will be raised. Therefore, the present invention is to provide a better manufacturing method of the conductive composition than the prior arts in order to overcome these shortcomings.

### SUMMARY OF THE INVENTION

Based on the above, an embodiment of the present invention provides a solar cell with a conductive composition formed as a positive electrode or a back electrode of the solar cell, wherein the conductive composition comprises a conductive functional phase mixture, wherein the conductive functional phase mixture is made of a metal and a metal oxide, wherein the metal oxide is as a filler and the metal is as a main body to enhance adhesion. The metal oxide includes 2-4 valent metal. A conductive coating portion may be optionally covering substantially at least a partial surface of the filler, wherein the coating portion includes at least metal or alloy to enhance conductivity. Melting point of the metal oxide is greater than a sintering temperature.

The metal oxide includes aluminum oxide, zirconium oxide, silicon oxide, zinc oxide, cupric oxide and the combination thereof.

The conductive composition further comprises a glass and an additive, wherein the metal oxide, the glass and the additive are mixed with an organic vehicle.

Another objective of the present invention provides a solar cell with a conductive composition formed as a positive electrode or a back electrode of the solar cell, wherein the conductive composition comprises a conductive functional phase mixture, wherein the conductive functional phase mixture is made of a metal and a metal oxide, wherein the metal oxide is as a filler and the metal is as a main body to enhance adhesion; and a conductive coating portion covering substantially at least a partial surface of the filler, wherein material cost of the filler is less than that of the conductive coating portion.

### BRIEF DESCRIPTION OF THE DRAWINGS

The components, characteristics and advantages of the present invention may be understood by the detailed descriptions of the preferred embodiments outlined in the specification and the drawings attached:

FIG. 1 illustrates a cross-section view of a silicone substrate of a solar cell;

FIG. 2 illustrates a cross-section view of a structure of silicon wafer solar cells;

FIG. 3 illustrates a manufacturing flow chart of the conductive composition used for the solar cell of the present invention;

FIG. 4 illustrates a testing graph of an adhesion;

FIGS. 5 and 6 illustrate a microscopic structure of alumina particles observed by using a scanning electron microscope (SEM);

FIGS. 7, 8 and 9 illustrate a microscopic structure of Al/alumina particles observed by using a SEM;

FIGS. 10, 11 and 12 illustrate a microscopic structure of alumina particles observed by using a SEM;

FIGS. 13˜18 illustrate an adhesion as face up and face down in the sintering process;

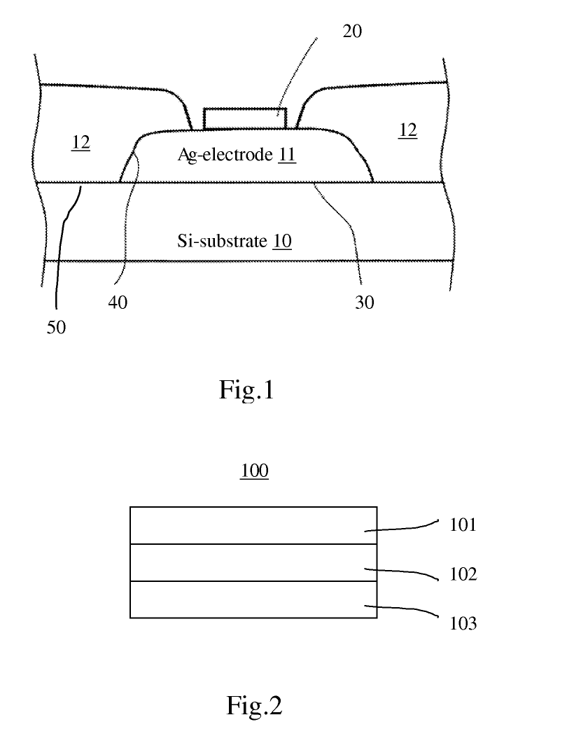

### DETAILED DESCRIPTION

Some preferred embodiments of the present invention will now be described in greater detail. However, it should be recognized that the preferred embodiments of the present invention are provided for illustration rather than limiting the present invention. In addition, the present invention can be practiced in a wide range of other embodiments besides those explicitly described, and the scope of the present invention is not expressly limited except as specified in the accompanying claims.

References in the specification to “one embodiment” or “an embodiment” refers to a particular feature, structure, or characteristic described in connection with the preferred embodiments is included in at least one embodiment of the present invention. Therefore, the various appearances of “in one embodiment” or “in an embodiment” do not necessarily refer to the same embodiment. Moreover, the particular feature, structure or characteristic of the invention may be appropriately combined in one or more preferred embodiments.

As shown in FIG. 2, it shows a cross-section view of a structure of silicon wafer solar cells. The structure of the silicon wafer solar cell is only one embodiment of the present invention, but not intended to limit the present invention of the structure of the silicon wafer solar cell and the method thereof. As shown in FIG. 2, silicon wafer solar cell 100 includes a first electrode 101, a second electrode 103 and a P-N semiconductor layer 102; the two electrodes are electrically conductive, of which at least one electrode is transparent. The P-N semiconductor layer 102 is configured on a first surface of the first electrode 101.

The first electrode 101 (known as a working electrode or a semiconductor electrode) includes any materials with electrical conductivity. For example, the first electrode 101 may be formed by a glass, PET PEN plastic with an Indium tin oxide (ITO) or Fluorine tin oxide (FTO) coated thereon, or a conductive macromolecule. The second electrode 103 (known as a back electrode) also includes any materials with electrical conductivity. The second electrode 103 includes a conductive substrate which may be formed by selecting from ITO, FTO, a metal sheet with coated titanium, zinc oxide, Ga₂O₃, Al₂O₃, Tin base oxide and the composition thereof. In one embodiment, material of the first electrode 101 and the second electrode 103 may be any combination of transparent material and non-transparent material.

It should be noted that a conductive composition of the present invention can be applied to the front-side or back-side of any type silicon wafer solar cells. In other words, the disclosed conductive composition can be applied to the positive electrode or the back electrode.

Whichever, for the back electrode example, the present invention discloses a conductive composition, which may be applied to be as material of the back electrode and manufacturing method thereof. The conductive composition comprises a conductive functional phase mixture made of a metal and a metal oxide, wherein the metal oxide is employed as the filler and the metal functions as the main body to enhance the adhesion; the metal of the metal oxide is 2-4 valent metal. A coating portion may cover substantially at least a partial surface of the filler, wherein the coating portion includes at least metal or alloy to improve the conductivity. The melting point of the metal oxide is greater than the sintering temperature. Percent by weight of the filler is 3 to 5. When the conductive particles of the metal oxide with coated the coating portion is performed by a heat treatment process, the surface of the coating portion flows to fill the gap there between the metal oxide, which can enhance the binding strength between the conductive compositions and thereby enhancing the conductivity and lowering the impedance. Moreover, cost of the material of the filler and the coating portion can be lower than that of the main body to achieve low-cost materials to replace high-cost core, but increase the adhesion and conductivity.

In the accompanying drawings and embodiments, manufacturing method of the conductive composition of the present invention will be described.

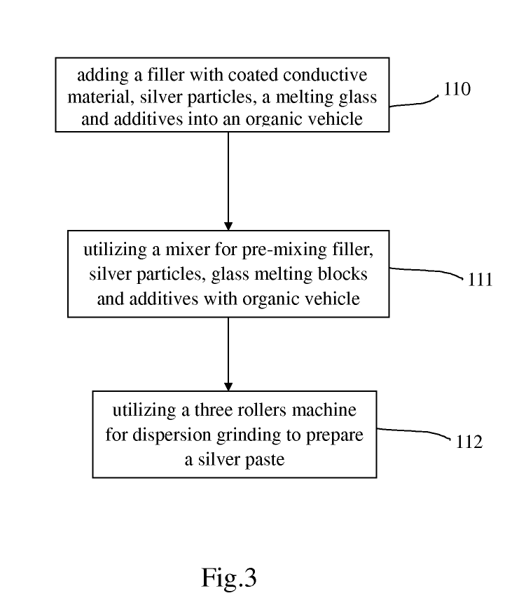

As shown in FIG. 3, it shows a manufacturing flow chart of the conductive composition used for the solar cell of the present invention. First, in step 110, a filler with conductive material coated thereon, silver particles, a melting glass (glass frit) and additives are added into an organic vehicle. Shape of particles contains flakes, spherical, columnar, massive, or the others non-specified shape with available size. Range of the particle size is about 0.1 to 10 microns (um). The organic vehicle may be selected from hydroxyl propyl cellulose (HPC), polyethylene glycol (PEG), polyethylene oxide (PEO), polyvinyl alcohol (PVA) or polyvinyl pyrrolidone (PVP) or other polymer resin. The organic vehicle can be employed to improve the dispersion of the filler and the silver particles, and further increase the adhesion to the substrate.

Subsequently, in step 111, it utilizes a mixer for pre-mixing, for example utilizing strongly stifling, ultrasonic vibrating (about 5 to 10 minutes) or homogenizer for mixing the pre-dispersed solution with the organic vehicle; that is mixing the filler, the silver particles, the glass melting blocks (glass frit) and the additives with the organic vehicle. Finally, in step 112, it utilizes a three rollers machine for dispersion grinding to prepare a silver paste, namely, the formation of the conductive composition.

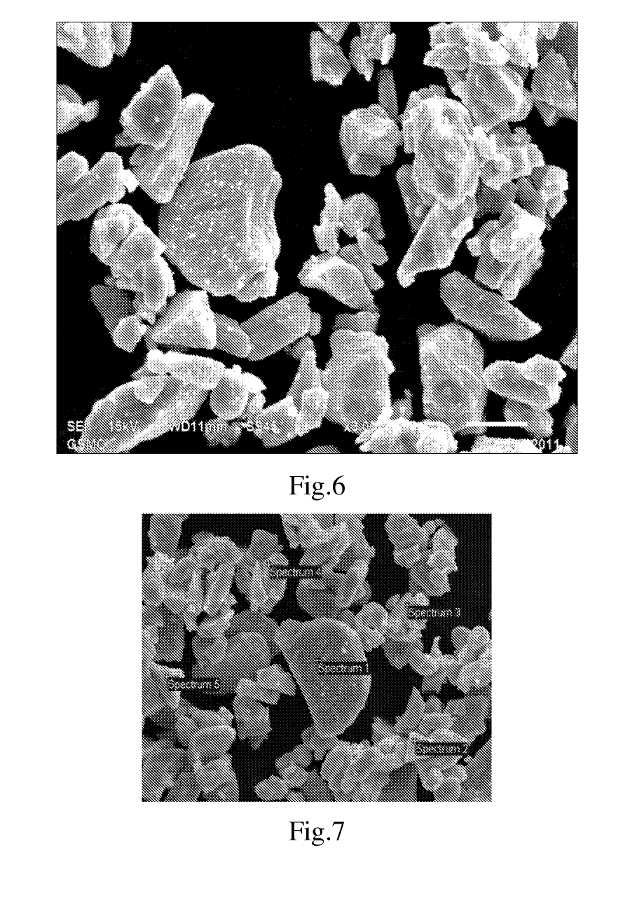

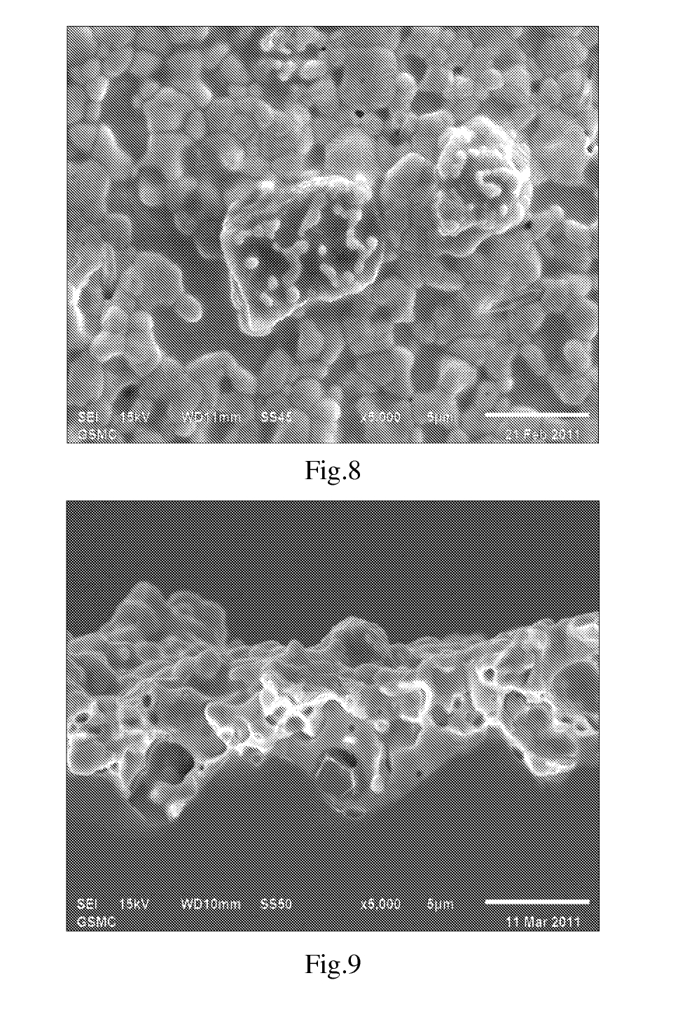

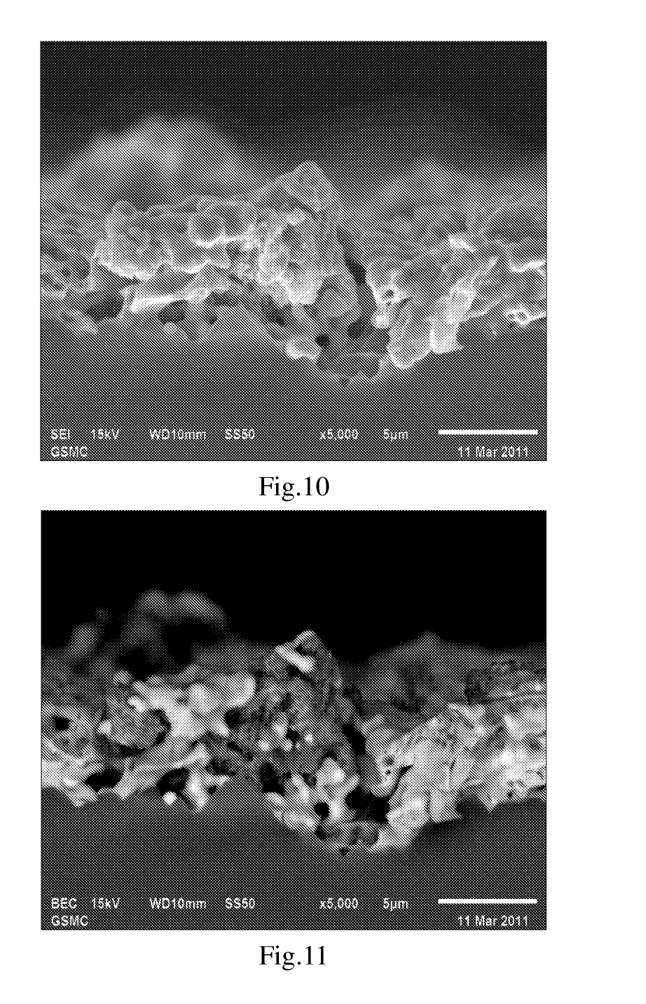

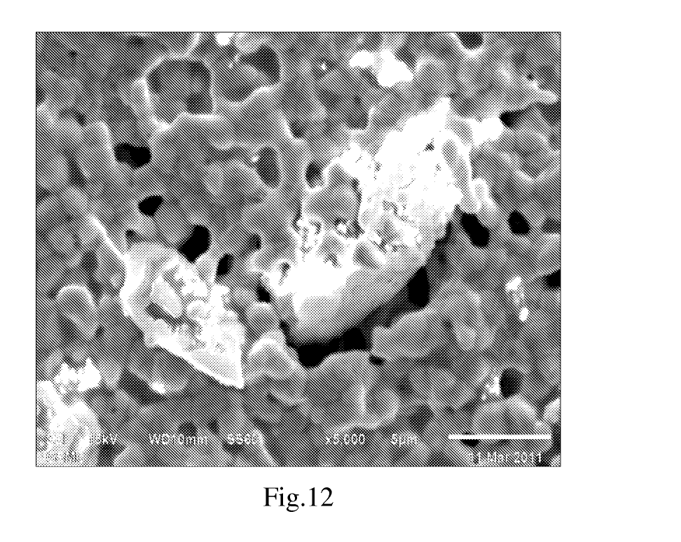

The formation of alumina is shown in FIG. 5 and FIG. 6 which shows a microscopic structure of alumina (powder) particles observed by using a scanning electron microscope (SEM). FIG. 7, FIG. 8 and FIG. 9 show a microscopic structure of Al/alumina particles observed by using a SEM. FIG. 10, FIG. 11 and FIG. 12 show a microscopic structure of alumina particles observed by using a SEM.

FIG. 7 shows a microscopic structure of particles of the silver/alumina powder in a different spectrum.

| element | Weight % | atomic weight % |
|---|---|---|
| O | 36.07 | 58.09 |
| Al | 37.20 | 35.52 |
| Ag | 26.73 | 6.39 |
| Total | 100.00 | |

### Spectrum 4

| element | Weight % | atomic weight % |
|---|---|---|
| O | 25.66 | 49.09 |
| Al | 35.06 | 39.77 |
| Ag | 39.28 | 11.14 |
| Total | 100.00 | |

### Spectrum 4

| element | Weight % | atomic weight % |
|---|---|---|
| O | 38.77 | 61.55 |
| Al | 34.05 | 32.05 |
| Ag | 27.18 | 6.40 |
| Total | 100.00 | |

### Spectrum 5

| element | Weight % | atomic weight % |
|---|---|---|
| O | 19.97 | 40.31 |
| Al | 39.81 | 47.65 |
| Ag | 40.22 | 12.04 |
| Total | 100.00 | |

### Spectrum 1

| element | Weight % | atomic weight % |
|---|---|---|
| O | 34.49 | 59.92 |
| Al | 30.05 | 30.95 |
| Ag | 35.46 | 9.14 |
| Total | 100.00 | |

### Spectrum 2

The conductive composition of the present invention is prepared by adding metal oxides as the filler. The surface of the filler is preferably coating a conductive layer, such as metal, alloy and the combination thereof. The material of the filler is, for instance, alumina (aluminum oxide), zirconium oxide, silicon oxide, zinc oxide, cupric oxide and the combination thereof. The filler is performed by a surface modification, and its surface is coated with a silver or copper metal layer to achieve the purpose of increasing adhesion, and thus increasing the peeling strength between silver-silver interface, and increasing the peeling strength between silver-glass interface; and thereby achieving the purpose of cost reduction of the metal oxide filler. In one embodiment, the conductive compositions of the present invention can be used in the front or back side of the solar cell.

The formed conductive composition can be performed by a screen printing process to form a conductive film, wherein the specification of the screen plate is for example a stainless steel screen fabric with 250 mesh, diameter of 35 microns (um), emulsion with thickness of 5 microns; printed graphic 153 mm*4.4 mm*2 Line. The silver paste is utilized by a screen printing to print on the back of the silicon substrate, in drying temperature of 200-300° C., time of 0.5-1 minutes. Then, it is using infrared sintering furnace for sintering by chain belt moving in peak temperature such as 700-900° C.

Next, according to the measurement program, in soldering for a solder ribbon, the cutting machine cut the solder ribbon with about 25 centimeters (cm), and soldering flux is coated on the solder ribbon to remove the oxide layer. Specifications of the solder ribbon are as follows:

| | Specification |
|---|---|
| Solder Ribbon | Sn = 62%; Pb = 36%; Ag = 2% |
| Copper core | 0.16 mm*2 mm |
| Coating thickness | 20 ± 5 (microns) |
| Melting temp. | 179° C. |

Based-on infrared soldering machine, the test components (solar cells) are placed on the platform of the machine, wherein the platform temperature sets to 140° C., and then the solder ribbon placing on the busbar of the solar cells, followed by soldering by the set time and temperature. The soldering conditions are as follows:

| | | |
|---|---|---|
| Hot plate temp (° C.) | 140° | C. |
| Heating time (s) | 4 | s |
| Cooling time (s) | 4.5 | s |

| | |
|---|---|
| IR Power/Actual temp | 65%/240° C. |

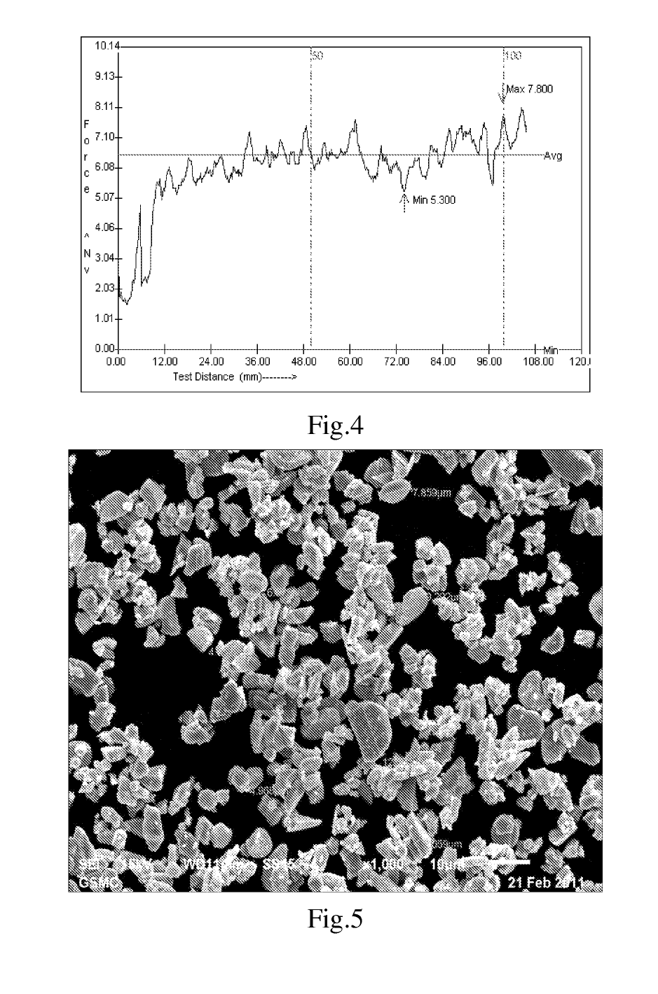

In addition, in the adhesion testing, the solar cells are fixed on the platform of a adhesion machine, and one end of the solder ribbon is fixed by a jig. The solder ribbon is pulled with angle of 180 degree, and by speed of 120 mm/s to measure and obtain the adhesion value. Results can refer to FIG. 4.

### Embodiment 1

| | | Ag/Alumina | Alumina | Ag | Weight |
|---|---|---|---|---|---|
| | | (wt %) | (wt %) | (wt %) | (g) |
| R395-1 | Contrast | 0 | 0 | 60 | 0.070 |
| R448 | Group D | 4 | 0 | 56 | 0.070 |
| R450 | Group E | 0 | 2 | 58 | 0.070 |
| R451 | Group F | 0 | 4 | 55 | 0.070 |

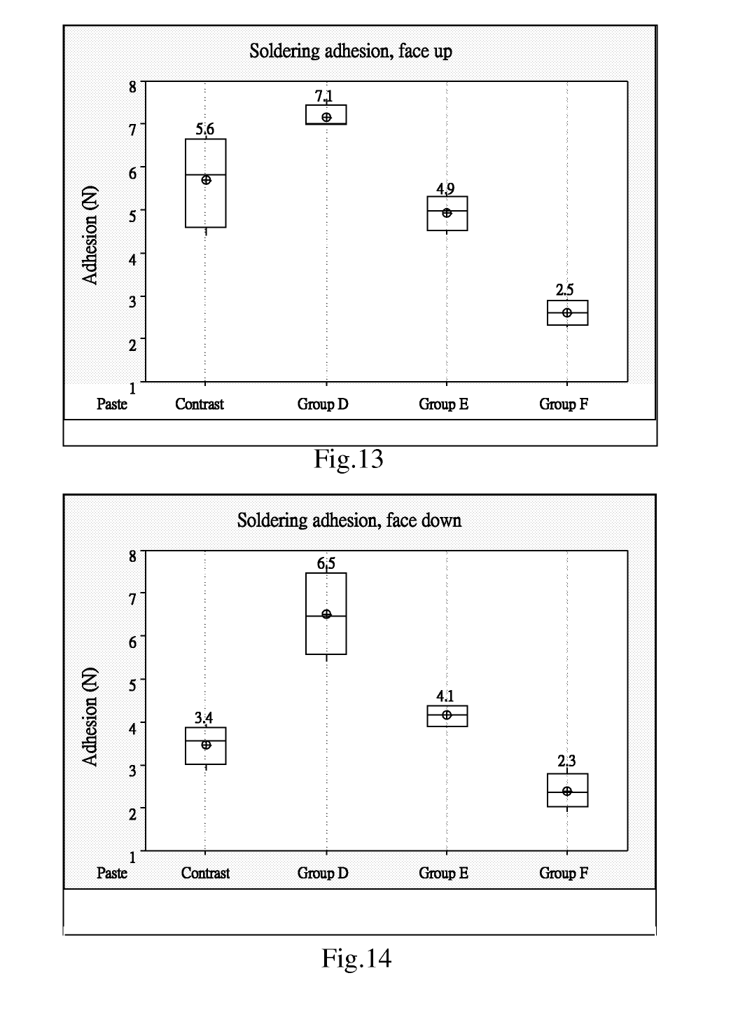

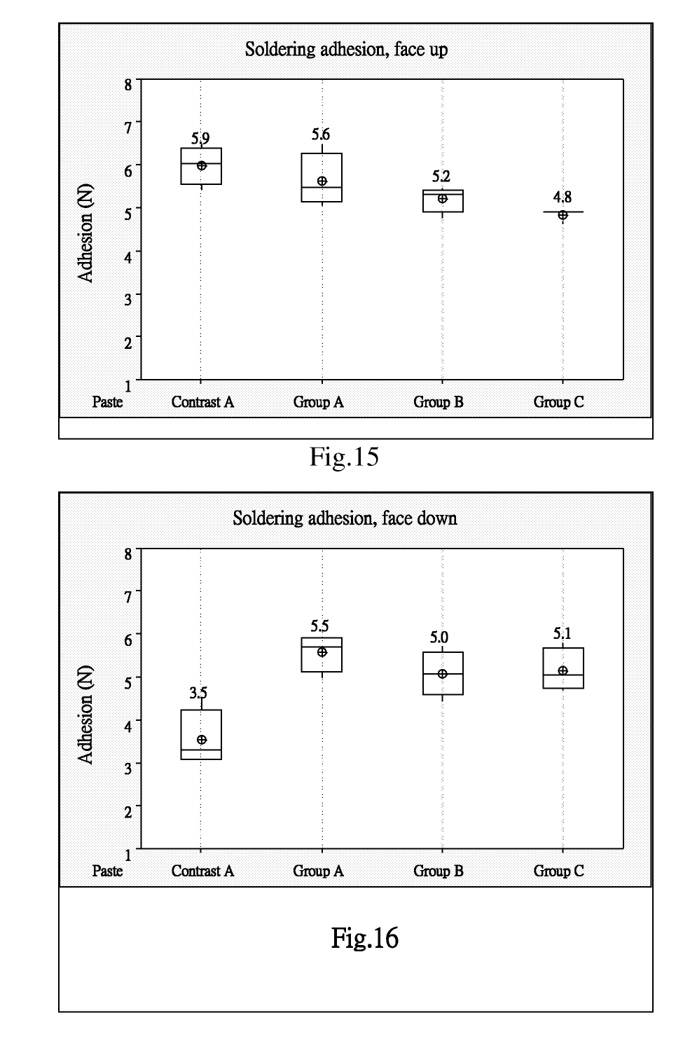

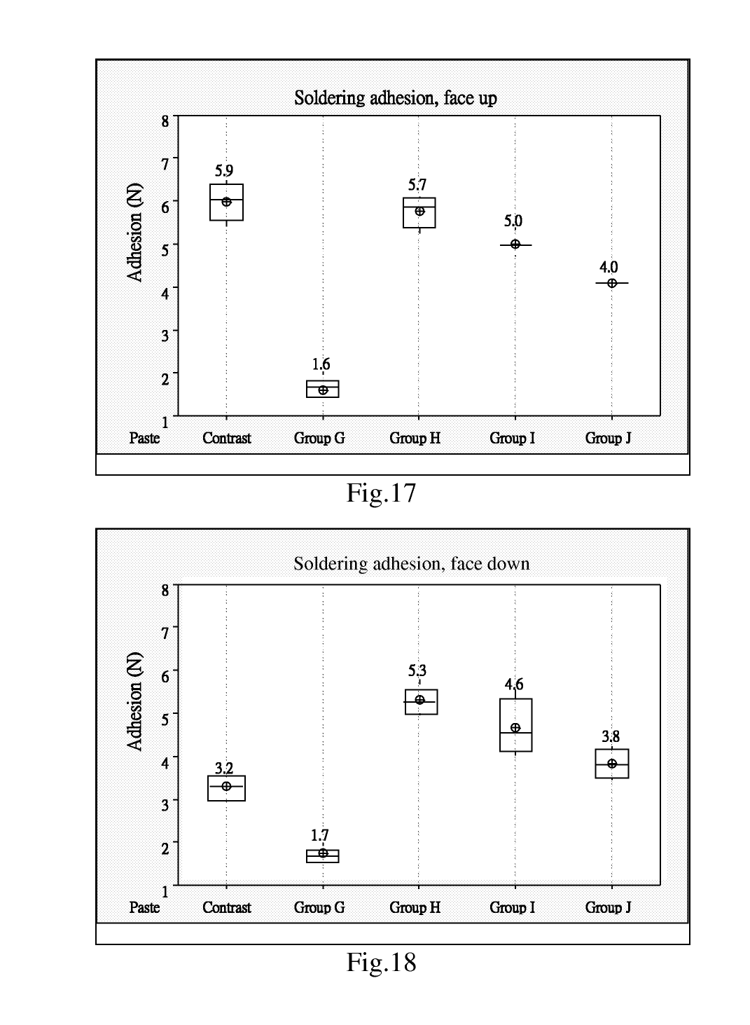

In the embodiment 1, it indicates that Ag/Alumina and the alumina content make an impact for the adhesion; adding alumina powder is not easily dispersed, and not easy to bond with silver to result in cracking in the sintering process. The adhesion as face up and face down in the sintering process refers to FIG. 13 and FIG. 14, respectively.

### Embodiment 2

| | | Ag/Alumina | Ag | Weight |
|---|---|---|---|---|
| | | (wt %) | (wt %) | (g) |
| R395-1EG | Contrast | 0 | 60 | 0.070 |
| R395-1EGA | Group A | 2 | 58 | 0.070 |
| R395-1EGB | Group B | 4 | 56 | 0.070 |
| R395-1EGC | Group C | 6 | 54 | 0.070 |

In the embodiment 2, it indicates that Ag/Alumina content make an impact on the adhesion; adding adequate Ag/Alumina to obtain a stable and high adhesion in the different sintering temperatures. The adhesion as face up and face down in the sintering process refers to FIG. 15 and FIG. 16, respectively.

### Embodiment 3

| | | Ag/Alumina | Ag | Weight |
|---|---|---|---|---|
| | | (wt %) | (wt %) | (g) |
| R395-1EG | Contrast | 0 | 60 | 0.078 |
| R395-1EGE | Group G | 0 | 54 | 0.065 |
| R395-1EGB | Group H | 4 | 56 | 0.078 |
| R395-1EGC | Group I | 4 | 54 | 0.072 |
| R395-1EGD | Group J | 4 | 52 | 0.068 |

In the embodiment 3, it indicates that Ag/Alumina content make an impact on the adhesion; lowering the content of silver, lowering printing volume, weak layer of silver can not be as a strong structural support. Ag/Alumina may be added to enhance the bonding strength between Ag—Ag and between Ag-glass. The adhesion as face up and face down in the sintering process refers to FIG. 17 and FIG. 18, respectively.

From above-mentioned, in the present invention, the filler, for example Ag/Alumina (zirconium oxide, silicon oxide, zinc oxide), may be adequately added into the conductive composition to enhance the adhesion and avoid the section of the original silver layer such that the conductive composition has an excellent electrical conductivity, and lower resistance.

### Embodiment 4

| | | | | | | adhesion | adhesion |
|---|---|---|---|---|---|---|---|
| | | Ag/Alumina | Alumina | Ag | Weight | as face | as face |
| | | (wt %) | (wt %) | (wt %) | (g) | up | down |
| K20 | Contrast | 0 | 0 | 53 | 0.063 | 1.73 | 1.51 |
| K21 | Group K | 4 | 0 | 50 | 0.063 | 4.05 | 3.85 |
| K23 | Group L | 0 | 2 | 50 | 0.063 | 3.94 | 3.81 |
| K24 | Group M | 0 | 3 | 50 | 0.063 | 4.97 | 5.18 |
| K25 | Group N | 0 | 4 | 50 | 0.063 | 3.28 | 3.10 |

In this embodiment, alumina is added into the conductive composition which silver is as a main body. From the embodiment 4, the contrast group contains only silver (Ag), and the contrast group does not add any of alumina, wherein the adhesion for facing up and the adhesion for facing down is 1.73 and 1.51, respectively. Based on the results of experiment and observation of the present invention, it can improve the adhesion by adding a small amount of alumina. The percent by weight of alumina is about 0.5-5, and the percent by weight of alumina is preferred about 2-4. It should be noted that the above table indicates the adhesion of the experimental group (K, L, M, N) is greater than that of the contrast group. Therefore, similarly, as the embodiment 4 shows that lowering the content of silver, lowering printing volume, weak layer of silver can not be as a strong structural support. Ag/alumina may be added to enhance the bonding strength between Ag—Ag and between Ag-glass. In addition, Alumina may also be added to create the same effect, and it can be filled in the voids caused by the decline of silver content (more fragile silver layer structure). The present invention provides a conductive composition comprising a mixture with conductive function which made of the metal and metal oxide, wherein the metal oxide is as a filler material and the metal is as a main body to enhance adhesion; wherein the metal contains silver, in which the percent by weight of alumina is about 0.5-5. The metal oxide includes aluminum oxide (alumina), zirconium oxide (zirconia), silicon oxide (silica), zinc oxide, cupric oxide and the combination thereof, and the metal oxide includes 2-4 valent metal.

The foregoing descriptions are preferred embodiments of the present invention. As is understood by a person skilled in the art, the aforementioned preferred embodiments of the present invention are illustrative of the present invention rather than limiting the present invention. The present invention is intended to cover various modifications and similar arrangements included within the spirit and scope of the appended claims, the scope of which should be accorded the broadest interpretation so as to encompass all such modifications and similar structures.

What is claimed is:

1. A solar cell, comprising:
electrodes formed by applying a conductive functional phase mixture onto a silicon wafer and sintering said conductive functional phase mixture and said silicon wafer;
wherein said conductive functional phase mixture comprises a metal as a main body and a metal oxide as a filler to enhance adhesion to said silicon wafer;
wherein said metal oxide is selected from one or more of aluminum oxide (alumina), zirconium oxide (zirconia), zinc oxide, cupric oxide; and
percent by weight of said metal oxide of said conductive functional phase mixture is from about 0.5% to about 5%.

2. The solar cell of claim 1, wherein said metal comprises silver and a ratio of said metal oxide to said metal is from about 2/50 to 4/50.

3. The solar cell of claim 1, wherein said metal oxide is aluminum oxide and percent by weight of said aluminum oxide is from 2% to 4%.

4. The solar cell of claim 1, wherein said conductive functional phase mixture and said silicon wafer is sintered at a sintering temperature lower than a melting point of said metal oxide

5. The solar cell of claim 4, wherein said sintering temperature is from about 700° C. to about 900° C.

6. A solar cell, comprising:
electrodes formed by applying a conductive functional phase mixture onto a silicon wafer and sintering said conductive functional phase mixture and said silicon wafer;
wherein said conductive functional phase mixture comprises a metal containing silver as a main body and a metal oxide as a filler been coated at least a partial surface of said metal to enhance adhesion to said silicon wafer by increasing peeling strength between silver-silver interface and by increasing peeling strength between silver-glass interface;
wherein said metal oxide is selected from one or more of aluminum oxide (alumina), zirconium oxide (zirconia), zinc oxide, cupric oxide; and
percent by weight of said metal oxide of said conductive functional phase mixture is from about 0.5% to about 5%.

7. The solar cell of claim 6, wherein a ratio of said metal oxide to said silver is from about 2/50 to 4/50.

8. The solar cell of claim 6, wherein said metal oxide is aluminum oxide and percent by weight of said aluminum oxide is from 2% to 4%.

9. The solar cell of claim 6, wherein said conductive functional phase mixture and said silicon wafer is sintered at a sintering temperature lower than a melting point of said metal oxide

10. The solar cell of claim 9, wherein said sintering temperature is from about 700° C. to about 900° C.
